(19) United States
(12) Patent Application Publication
(10) Pub. No.: US 2004/0053440 A1
(43) Pub. Date: Mar. 18, 2004

(54) Method and apparatus of carbon nanotube fabrication

(75) Inventors: Jonathan W. Lai, Santa Barbara, CA (US); Dennis M. Adderton, Santa Barbara, CA (US); Stephen C. Minne, Santa Barbara, CA (US)

Correspondence Address: Jay G. Durst, Suite 1030, 250 E. Wisconsin Avenue, Milwaukee, WI, 53202, US

(73) Assignee: First Nano, Inc., Santa Barbara, CA

(21) Appl. No.: 10/402,455

(22) Filed: Mar. 28, 2003

Related U.S. Application Data
(60) Provisional application No. 60/405,231, filed on Aug. 21, 2002.

(51) Int. Cl. H01L 21/00; C30B 1/00; C23C 16/00

(52) U.S. Cl. 438/105; 438/478; 118/715

(57) ABSTRACT

A method of fabricating carbon nanotubes in a nanotube growth apparatus including executing a nanotube growth process recipe and monitoring a safety condition during the executing step. The executing step is interlocked to the monitoring step such that the executing step can be aborted based on the output of the monitoring step.

### BACKGROUND OF THE INVENTION

1. Field of the Invention

The present invention is directed to the fabrication of carbon nanotubes, and more particularly, a safety mechanism and method for use in a system for growing carbon nanotubes.

2. Description of Related Art

Since their discovery over a decade ago, carbon nanotubes have shown great promise in a wide variety of technologies, including extending Moore's Law beyond the physical limitations of known silicon techniques. Carbon nanotubes are much like elongated Bucky balls, a form of carbon-composed clusters of approximately 60 carbon atoms, bonded together in an apolyhedral, or many-cited structure composed of pentagons and hexagons, like the surface of a soccer ball. Shaped-like cylinders of chicken wire, nanotubes may comprise single-walled or concentric multi-walled tubes that range, for example, between 0.4 and 20 nanometers thick. Generally, single-walled carbon nanotubes are preferred over multi-walled carbon nanotubes for use in the applications contemplated by the present invention because they have fewer defects and are therefore stronger and more conductive than multi-walled carbon nanotubes of similar diameter.

Notably, nanotubes can be at least a 100 to 1000 times stronger than the strongest steel and have excellent electron-emission capabilities. What makes such structures even more appealing is their durability. When used as probe tips for atomic force microscopy, attempts to “crash” or damage the tubes have proved difficult due to the inherent flexibility that allows them to return to their original shape. Overall, the unique properties of nanotubes make them suitable for nanometer scale wires, transistors, quantum devices and sensors. Moreover, carbon nanotubes can be engineered to act as metallic conductors, semi-conductors, insulators or diode junctions, for example, and modeling predicts that they may also be made to exhibit super conductivity and magnetism.

One challenge in the field of producing carbon nanotubes is been how to exploit the structures for use in the desired applications, such as in field emission devices. On the microscopic level, nanotubes have typically been made by processes resulting in tubes that are inconveniently integrated in a twisted clump. For example, nanotubes have been produced by vaporizing carbon with an electric current. In this case, the vapor condenses to form a sooty clump, rich in nanotubes. One wanting to extract such nanotubes, however, has to then painstakingly tease out individual tubes for use in their experimental research. For example, in the manufacture of carbon nanotube atomic force microscopy probes, workers typically will mine the clump with, for example, cellophane tape, and then lightly touch a glue-dipped conventional tip to the wad of nanotube bundles and gingerly pluck each tube out. This type of bulk production and extraction of nanotubes is generally unworkable. As a result, techniques have since been developed to precisely pattern the carbon nanotubes on a substrate according to a user's particular requirements. Moreover, in this case, such “teasing” of the tubes is eliminated.

For instance, elongated bucky balls, or nanotubes, are now being grown on a substrate in a well-aligned manner, resembling a wheat field. More specifically, nanotubes are often grown on a substrate by catalytic decomposition of hydrocarbon-containing precursors such as ethylene, methane or benzene. In this fashion, nanotubes can be made in the form of a collection of free-standing nanoconnectors substantially equal in length. In one application, carbon nanotubes are patterned into individual field emitters to provide an array of emitters which may be used in applications such as flat panel displays.

In general, catalyzed chemical vapor deposition (CVD) has been employed for the growth of carbon nanotubes in a process that is both scalable and compatible with integrated circuit and MEMS manufacturing processes. Notably, CVD allows high specificity of single wall or multi-wall nanotubes through appropriate selection of process gases and temperature. The carbon feed stock is generated by the decomposition of a feed gas such as methane or ethylene. The associated high stability of the feed gas prevents it from decomposing in the elevated temperatures of the nanotube fabrication furnace, which is typically 700 to 1000 degrees Celsius.

Preferably, decomposition of the feed gas occurs only at the catalyst sites, thus reducing amorphous carbon generated in the process. Decomposed carbon molecules then assemble into nanotubes at the catalyst nano-particle sites. Advantageously, catalyst nano-particles can be patterned on a substrate lithographically to realize nanotube growth at intentional locations, as suggested previously. For example, the growth of nanotubes can be caused to originate at a site of electrical connections or of mechanical significance.

Overall, carbon nanotubes have been demonstrated as enabling components for various electronic and chemical-mechanical devices functional on the molecular scale. Notably, in addition to enabling nano-scale electronic devices, nanotubes are proving to be useful for chemical and biological sensing. Semi-conducting carbon nanotubes have been used at Stanford University to detect gas molecules, and semi-conductor nanowires have been used as ultra sensitive detectors for a wide range of biological compounds. Such devices include chemical for sensors, gas detectors, field emission displays, molecular wires, diodes, FET's, and single-electron transistors.

Nevertheless, one critical issue with respect to the development of devices that use carbon nanotubes as building blocks is that the fabrication of such tubes can be dangerous. To develop such devices into manufacturable products and gain control of device assembly on the molecular level, a more practical and safe system for in situ nanotube growth is needed.

In this regard, the relatively low temperatures of the process and the ability to pattern the catalytic material directly on device substrates make catalytic pattern CVD the preferred choice for nanotube device development. During process, however, the furnace in which the nanotubes are grown can be several hundred degrees Celsius, as noted above. Under this condition, if the carbon feed gas is introduced to a process chamber where a significant amount of oxygen present, an explosion will likely result. If the operator introduces oxygen into the enclosure used to grow the nanotubes, for instance, by opening the enclosure during, or soon after, process, there is a high risk that an explosion will occur.

Moreover, because gas plumbing, flow control units and the gas mixing manifold are maintained in proximity to one another, the risks associated with a potential gas leak are particularly high. Therefore, how such combustible gasses are exhausted and how the system responds to a potentially dangerous condition are limiting factors to the usefulness of current nanotube growth systems. Overall, the combustible gasses employed in nanotube fabrication may lead to potentially catastrophic results. So again, the art of producing carbon nanotubes, and devices employing carbon nanotubes, is in need of an apparatus and method that maximizes safety during all stages of the nanotube growth process.

### SUMMARY OF THE INVENTION

The preferred embodiment is directed to a carbon nanotube fabricating system and method that employs control automation to ensure safety during the fabrication of nanotubes in a variety of applications. In particular, control automation is employed to minimize the chance that process gases interact with dangerous amounts of oxygen during any step in the process of fabricating nanotubes by purging oxygen from the process chamber of the furnace at appropriate times in the fabrication routine, and interlocking execution of a growth recipe based on critical sensor outputs.

According to a first aspect of the preferred embodiment, a method of fabricating carbon nanotubes in a nanotube growth apparatus includes the steps of executing a nanotube growth recipe and simultaneously monitoring a safety condition during the executing step. In operation, the method includes continuously controlling the executing step based on the monitoring step.

According to another aspect of this preferred embodiment, the safety condition is associated with at least one of a group including a pressure in an exhaust pathway, a flow in the exhaust pathway and a predetermined amount of a combustible gas in the apparatus.

In a further aspect of this preferred embodiment, the executing step occurs for a predetermined time period. Moreover, the predetermined time period ideally defines a selected number of cycles, and the monitoring step includes reading a plurality of sensors. Preferably, the reading step is performed after each cycle.

According to yet another aspect of this preferred embodiment, the controlling step includes aborting the executing step in response to the monitoring step. Thereafter, the method preferably operates to purge the process chamber after the aborting step.

According to a further aspect of the preferred embodiment, a nanotube growth apparatus includes a furnace having a process chamber. The apparatus also includes a gas delivery unit and an exhaust sub-system coupled to the furnace and the gas delivery unit. A sensor is used to detect at least one of a group including a pressure in the apparatus, a gas flow in the apparatus and a presence of a combustible gas in the apparatus.

In another aspect of the preferred embodiment, the sensor generates an output signal during execution of a nanotube growth recipe and the output signal is transmitted to a computer. The computer controls execution of the nanotube growth recipe in response to the output signal. Preferably, once at least a first step of the nanotube growth recipe is executed, the computer processes the output signal after each of a predetermined number of cycles during execution of the first step.

According to yet another aspect of this preferred embodiment, the computer causes the apparatus to enter an abort state based on the output signal. The abort state relates to controlling at least one operation. The operation may be a purge operation to purge process gasses from the process chamber.

According to yet another aspect of this preferred embodiment, the apparatus includes a vacuum source for modifying a nanotube growth dynamic. This growth dynamic may be a growth rate.

In a still further aspect of the preferred embodiment, a monitoring system for a nanotube growth apparatus, the apparatus including a furnace having a process chamber, includes a network of sensors that measure at least one of a group of system conditions including gas flow, presence of a combustible gas and a pressure. The sensors each generate a corresponding fault signal which may or may not indicate a fault condition. Moreover, a control system interlocked to at least one of the fault signals to control operation of the nanotube growth apparatus is also provided.

According to another aspect of this preferred embodiment, a control system aborts operation of the nanotube growth apparatus based on the output of at least one of the fault signals. The control system may generate a purge signal in response to at least one of the fault signals, and then transmit the purge signal to a gas delivery unit to purge the process chamber with an inert gas. The monitoring system preferably also includes an exhaust sub-system, and at least one flow sensor is place in the exhaust sub-system. A network of sensors may be provided which includes at least one flow sensor positioned in the exhaust sub-system, at least one pressure sensor in the gas delivery unit, and at least one combustible gas detector in an enclosure of the nanotube growth apparatus.

According to yet another aspect of the preferred embodiment, a monitoring system for a nanotube growth apparatus having a furnace including a process chamber includes means for sensing at least one of a gas flow, a presence of a combustible gas and a pressure in the apparatus. Moreover, the system includes means for continuously controlling execution of a nanotube growth recipe based on an output of the sensing means.

In another aspect of the preferred embodiment, the monitoring system includes means for altering a reaction rate associated with the nanotube growth. The altering means is preferably a vacuum source. In this case, the vacuum source may be used to lower a pressure in the process chamber to slow nanotube growth.

These and other objects, features, and advantages of the invention will become apparent to those skilled in the art from the following detailed description and the accompanying drawings. It should be understood, however, that the detailed description and specific examples, while indicating preferred embodiments of the present invention, are given by way of illustration and not of limitation. Many changes and modifications may be made within the scope of the present invention without departing from the spirit thereof, and the invention includes all such modifications.

### BRIEF DESCRIPTION OF THE DRAWINGS

A preferred exemplary embodiment of the invention is illustrated in the accompanying drawings in which like reference numerals represent like parts throughout, and in which:

FIG. 1 is a schematic view of a nanotube fabrication furnace according to the preferred embodiment;

FIG. 2 is a flow-chart illustrating a method of purging gases in the process chamber to ensure safety during nanotube fabrication;

FIG. 3 is a flow-chart illustrating an alternate method of purging gases in the process chamber to ensure safety during nanotube fabrication;

FIG. 4 is a schematic diagram illustrating a nanotube fabrication system with safety interlocks according to the preferred embodiment; and

FIG. 5 is a flow-chart illustrating a method of process control based on information from condition sensors generated during nanotube fabrication.

### DETAILED DESCRIPTION OF THE PREFERRED EMBODIMENT

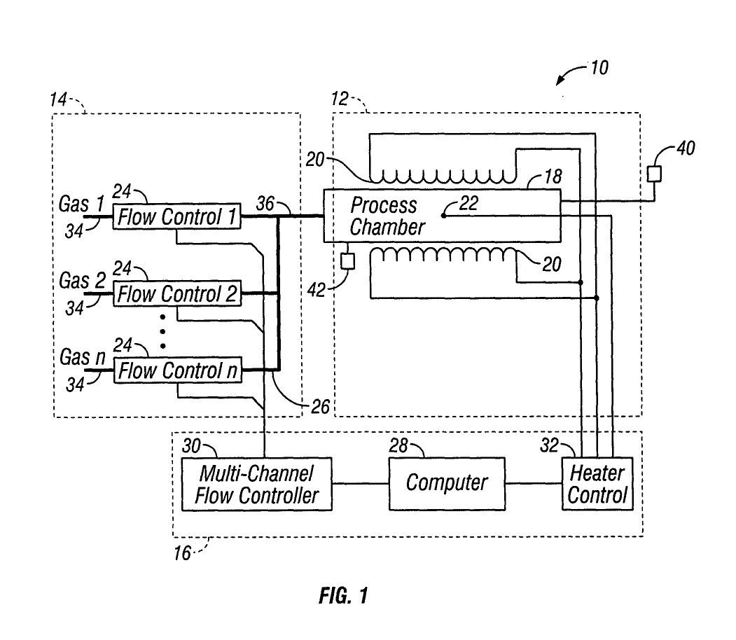

With reference to FIG. 1, a nanotube fabrication apparatus 10 includes a nanotube furnace 12 in which nanotubes are grown, and a gas delivery unit 14 that supplies appropriate gases to furnace 12 according to particular process operations. Apparatus 10 also includes a control unit 16 that coordinates growth of nanotubes according to user defined recipes and maintenance of safe operation of the system.

Furnace 12 includes a process chamber 18 configured to accommodate, for example, a substrate upon which nanotubes can be grown. Preferably, process chamber is a cylindrical quartz tube. However, process chamber 18 could also be constructed of another material resistant to high temperatures, such as alumina. Moreover, the process chamber need not be cylindrical. Surrounding process chamber 18 are heater elements with coils 20 that are insulated from the ambient environment so as to apply appropriate heat to process chamber when growing nanotubes according to process specifications. In addition, a temperature sensor 22 mounted in or around process chamber 18 is also included. Temperature sensor may comprise a probe that detects the temperature within chamber 18 and feeds back to the control unit 16 to precisely monitor the temperature during the growth cycle, or otherwise.

Gas delivery unit 14 includes a plurality of flow controllers 24, labeled 1-n, in FIG. 1, that are used to deliver the different process gases (correspondingly labeled 1-n) input to system 10 by input plumbing lines 34 to process chamber 18 of furnace 12. Flow controllers 24 are preferably mass-flow controllers which are well known in the art. Each flow controller 24 delivers a particular gas to a gas manifold 26 to allow mixing of the gases prior to introduction to process chamber 18. Alternatively, process chamber 18 itself could act as a gas manifold with the individual gases introduced directly to the chamber. This alternative may be employed for greater simplicity and lower cost, however, including gas manifold 26 is preferred for increased homogeneity in the gas mixture resulting in greater growth repeatability.

Control unit 16 includes a computer 28 that communicates with a multi-channel gas controller 30 that instructs the individual flow controllers 24 to deliver particular amounts of gas for particular amounts of time to gas manifold 26, and ultimately process chamber 18. During process, multi-channel gas controller 30 continuously communicates with flow control units 24 to monitor the amount of gas being delivered to gas manifold 26. In particular, mass-flow controllers 24 transmit signals to gas controller 30 that are indicative of the actual flow of gas output by each. Computer 28 also communicates with heater control unit 32 to appropriately increase/decrease the temperature within furnace 12 according to process defined requirements, including nanotube growth recipes.

### Purging Process Chamber

In operation, process gases are introduced to the system through flow control units 24. The process gases may be a single gas such as methane or ethylene, or may comprise a mixture of two or more gases including hydrogen, methane, ethylene, acetylene, benzene, and potentially others as known in the art of fabricating nanotubes. In addition to such process gases, one of flow control units 24 provides an inert gas such as argon.

To fabricate nanotubes with system 10, a process recipe is input to computer 28 of control unit 16. The process recipe generally consists of increasing the temperature of process chamber 18 to several hundred degrees Celsius and introducing a carbon rich gas to the process chamber 18. Other common recipe steps may include high temperature anneal, reduction reactions, or treatment in carbon free process gases. This carbon rich gas provides the fuel for the formation of the carbon nanotubes. Carbon feed gas, as known in the art, is typically reactive with oxygen at the temperatures at which carbon nanotube growth occurs. Therefore, at several hundred degrees Celsius, if the carbon feed gas is introduced to process chamber 18 with a significant amount of oxygen present, an explosion is the likely result, as noted previously. Moreover, the risk of explosion is high when producing nanotubes even without carbon feed gas present. As a result, the preferred embodiment operates to minimize the chance of explosion wherever a combustible process gas is present. For example, hydrogen, a combustible reagent used in nanotube fabrication processes, poses a significant explosion risk whenever present.

For example, therefore, prior to introducing the reactive gases to gas manifold 26, and ultimately the process chamber 18, apparatus 10 of the preferred embodiment purges the process chamber 18 with an inert gas in order to reduce the amount of oxygen residing therein to a safe level. Importantly, a purge operation may be initiated prior to, during or after execution of a nanotube growth recipe depending upon operation conditions. The way in which the inert gas is introduced to the system is described in further detail below.

A nanotube fabrication program stored in computer 28 is communicated to multi-channel gas controller 30 to instruct flow control units 24 to deliver the corresponding gas at a desired flow set-point, and for a predetermined time, according to the process recipe being run by computer 28. Again, heater control unit 32 applies power to the heater elements 20 of furnace 12 within an appropriate amount to maintain the temperature in process chamber 18 at a predetermined value as defined in the fabrication program being run by computer 28.

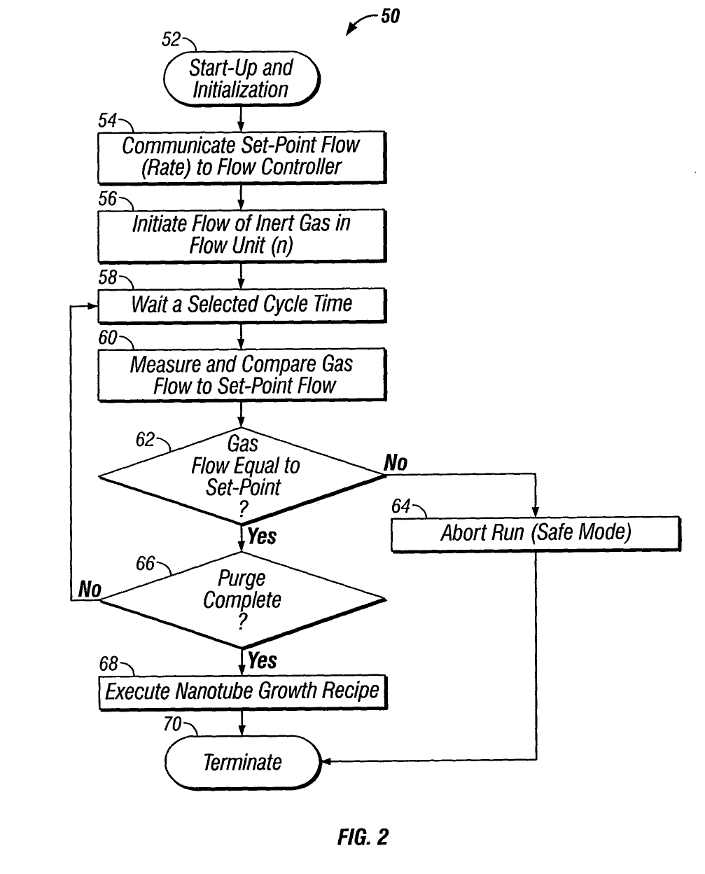

To minimize the chance that an explosion occurs, the purge routine is employed by system 10 to insure process chamber 18 is sufficiently purged of oxygen, thus ensuring a safe environment for the growth of the carbon nanotubes. In this regard, turning to FIG. 2, a method 50 includes a start-up and initialization Block 52. This step is initiated by an instruction from computer 28 to begin a recipe to grow nanotubes. Then, in Block 54, a flow set-point associated with insert gas channel, channel n, for example, is communicated to the multi-channel gas controller 30 (FIG. 1). Flow is defined as the volume of gas introduced to process chamber 18 per unit time. More specifically, in order to be certain that the process chamber 18 is sufficiently purged of oxygen, a predetermined volume of inert gas is to be delivered to process chamber 18. This is accomplished by programming a flow set-point and a predetermined period of time over which the flow (in this case, of inert gas) should continue. Note that to sufficiently purge the process chamber 18, the volume of purge gas should be greater than the volume of process chamber 18. This volume of purge gas is correctly metered to process chamber 18 by maintaining a specific flow over a period of time, each of which has been configured according to the flow and volume capacities of the system. This instruction is implemented via the program stored and communicated by computer 28 to multi-channel gas controller 30, and feedback signals transmitted between the control units 24 and the multi-channel gas controller 30 and processed thereby, in the preferred embodiment.

Next, in Block 56, method 50 initiates the flow of purge gas. The system is then instructed to wait for a selected amount of time in Block 58. This selected purge duration of the purge loop defines a cycle such that a total number of loop cycles multiplied by the time it takes for each cycle equals the desired or predetermined purge duration (Block 54) which provides a flow of inert gas corresponding to the predetermined volume. After each cycle (i.e., continuous flow for the time selected in Block 58), in Block 60, the actual gas flow is measured in conventional fashion and compared to the purge set-point. In other words, the actual flow of purge gas from the mass-flow controller 24 is compared to the value of the purge flow set-point communicated in Block 54.

Next, in Block 62, if the system is operating correctly, the two values compared in Block 60 will be approximately equal. Notably, some percentage error is allowed for control and measurement uncertainty. In the event of a problem, these values may not be equal. For example, one likely malfunction is the expiration of the purge gas reservoir (not shown). As the gas supply runs out, the pressure on the gas supply line drops and the flow through the purge gas channel decreases. In this case, the actual gas flow is less than the flow set-point and the difference is used subsequently in Block 62 of method 50 to decide the next appropriate step.

More particularly, in the event that the actual flow is not equal, with acceptable error, to the purge set-point, an abort run step, Block 64, is executed and the nanotube growth process is stopped in Block 70. The abort run step preferably places the system 10 (FIG. 1) in a safe condition and notifies the operator that an error has occurred. The characteristics of the safe condition depends on the point of operation. Again, the purge routine may be executed prior to initiation of a nanotube growth recipe (as specifically illustrated in FIG. 2) or may be executed upon completion of the steps of the nanotube growth recipe, two routine implementations of the purge operation. The safe condition may include stopping the flow of any combustible process gases to chamber 18, discontinuing any instruction to heat control unit (32 in FIG. 1), for example, to increase the temperature of process chamber 18, and locking out any potentially dangerous operator commands (for example, a command to open chamber 18) until the malfunction is rectified. For the case of FIG. 2, the nanotube growth recipe is not initiated, yielding fewer safety concerns.

If, on the other hand, the actual flow is generally equal to the flow set-point in Block 62, method 50 determines whether the purge is complete in Block 66 by calculating whether the predetermined volume of purge gas has been introduced to chamber 18. This is typically implemented via a calculation of the elapsed time after the beginning of the instruction to flow the gas in Block 56, i.e., by determining whether a sufficient number of cycles of inert gas flow have been completed. If the predetermined purge time has passed (i.e., the system has cycled the flow of inert gas a sufficient number of times), then a sufficient volume of purge gas has been delivered to the process chamber and the sequence continues to Block 68 to execute the nanotube growth recipe. If, on the other hand, the predetermined purged time has not passed, the sequence will loop back to Block 58 to wait until another cycle of the inert gas flow, at the set-point, is complete. Thereafter, the flow is again measured to make sure the flow of inert gas is at the set-point (Blocks 58, 60, 62, 66).

In the step of executing the nanotube growth recipe, Block 68, the sequence of controls to process chamber 18 with respect to temperature and process gas flow are initiated according to a recipe program communicated by control computer 28. As the details of such recipes are not the subject of the present invention, they are not included for the sake of brevity. Once the growth recipe has been executed, the method is terminated in Block 70.

Notably, Blocks 58 and 60 may be transposed in method 50 or Block 58 may be located in the sequence between Blocks 62 and 66 so that the gas flow is compared to the purge set-point prior to waiting for a selected cycle time while the flow of purge gas continues. In this case, a determination that the predetermined purge duration is not complete (Block 66) returns operation of method 50 to the compare step, Block 60. Apparatus 10 may also include a vacuum source 40, for example, a conventional vacuum source, to draw vacuum on process chamber 18 to modify the nanotube growth dynamics. For instance, vacuum control may be implemented to alter the reaction rate of nanotube growth by adjusting the amount of available carbon feed gas in the vicinity of the associated catalyst. Notably, lower pressure reduces reagent concentration available for nanotube growth thereby slowing the growth rate. Overall, by altering the reaction rate, the purity and quantity of the tubes may be adjusted.

In addition, apparatus 10 may include a pressure control valve 42 coupled to process chamber 18, and a device to adjust the valve 42 to maintain a desired pressure. In addition, concurrent with flowing the purge gas in Block 58, the process chamber may be heated or cooled to a desired temperature. This may be done in order to anneal or reduce the carbon nanotube catalyst. And, the apparatus may include a fluid or vapor delivery device to introduce fluids to process chamber 18. Such fluids may include catalyst solutions or carbon fuel liquids, such as certain alcohols.

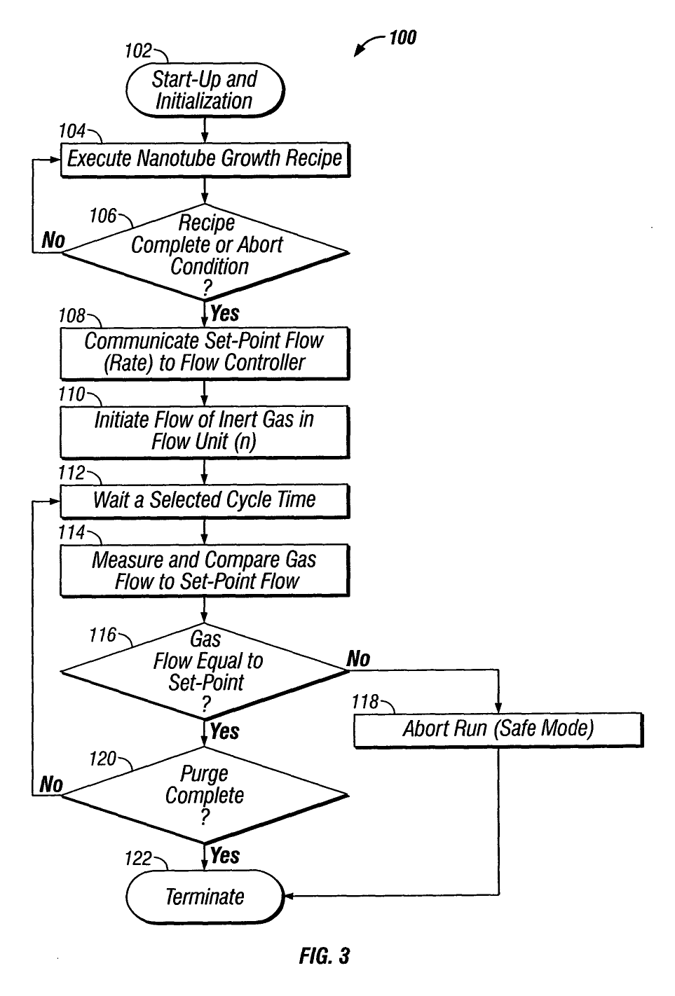

Additionally, turning to FIG. 3, a purge may be performed upon termination of the nanotube growth process. More particularly, a method 100 may be implemented to purge the chamber 18 after execution of any number of steps of a nanotube growth recipe, including after completion thereof. Block 68 in FIG. 2 may be expanded to include Blocks 104 through 120 in FIG. 3. Likewise, Block 104 in FIG. 3 may be expanded to include Blocks 54 through 68 in FIG. 2. After a start-up and initialization step, Block 102, the nanotube growth recipe is executed in Block 104. In Block 106, method 100 determines whether the nanotube growth receipt has either been aborted or completed. The details of the conditions under which the nanotube growth recipe may be aborted are set forth below with respect to the “interlocks” safety feature. If not, control returns to Block 104 to continue execution of the growth recipe.

If so, on the other hand, the nanotube growth recipe has been aborted or is otherwise complete. The purge routine in Block 108 is initiated by communicating a set-point inert gas flow signal to the appropriate channel of the multi-channel gas controller (30 in FIG. 1). Then, the flow controller, in response, begins the flow of purge gas in Block 110 at a rate equal to the set-point flow. In Block 112, method 100 waits while the inert gas purge continues for a selected amount of time, i.e., a cycle time. After the selected amount of time, the actual gas flow is measured and compared to the purge set-point in Block 114. In Block 116, method 100 determines whether this actual flow is at the set-point. If the gas flow is generally equal to the set-point, i.e., within the parameters of acceptable error, routine 100 determines whether the purge is complete in Block 120. Typically, this is done by noting the amount of time that has passed. If the flow is generally equal to the set-point, comparing the amount of the lapsed time to the predetermined amount of time associated with the particular volume of gas provides an indication of whether the purge is complete. If so, the routine 100 is terminated in Block 122. At this point, the chamber (18 in FIG. 1) may be opened by an operator without the risk of an explosion.

Alternatively, if, in Block 116, the gas flow is not equal to the set-point flow (again, within acceptable tolerances), the system is placed in a “safe mode” in Block 118 as the purge gas routine is aborted and method 100 stops in Block 122. The safe condition preferably includes stopping the flow of any combustible process gases to chamber 18, discontinuing any instruction to heat control unit (32 in FIG. 1) to increase the temperature of process chamber 18, and locking out any potentially dangerous operator commands (for example, a command to open chamber 18) until the malfunction is rectified.

### Interlocks

To further enhance safety during fabrication of nanotubes, a carbon nanotube growth system 200 can be configured to reduce the potentially harmful consequences of accumulated combustible waste gasses. If combustible gasses are allowed to accumulate within any enclosure of the instrument, or within the proximity of the instrument, an explosion is possible. Therefore, for safe operation, these gasses must be exhausted from the facility where the instrument is installed.

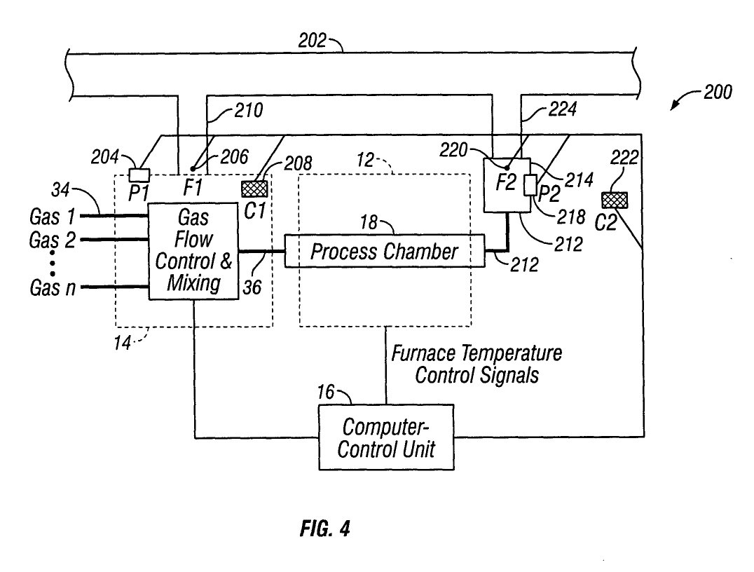

In FIG. 4, a facility exhaust 202 (i.e., exhaust sub-system) is shown connected to the nanotube growth system 200 in two places, via exhaust outlets 210 and 224. Initially, the gas delivery and control unit 14 via exhaust outlet 210 is exhausted in case of a failure of a component within unit 14. The potential of a leak here is of particular concern because the gas plumbing (34, 36 in FIG. 1), the flow control units (24 in FIG. 1) and the gas mixing manifold (26 in FIG. 1) are housed together within unit 14. Typically, unit 14 is vented to the room, allowing air to be drawn through the unit, into the facility exhaust. This serves to prevent the build up of a hazardous concentration of combustible gas should there be a leak within the unit.

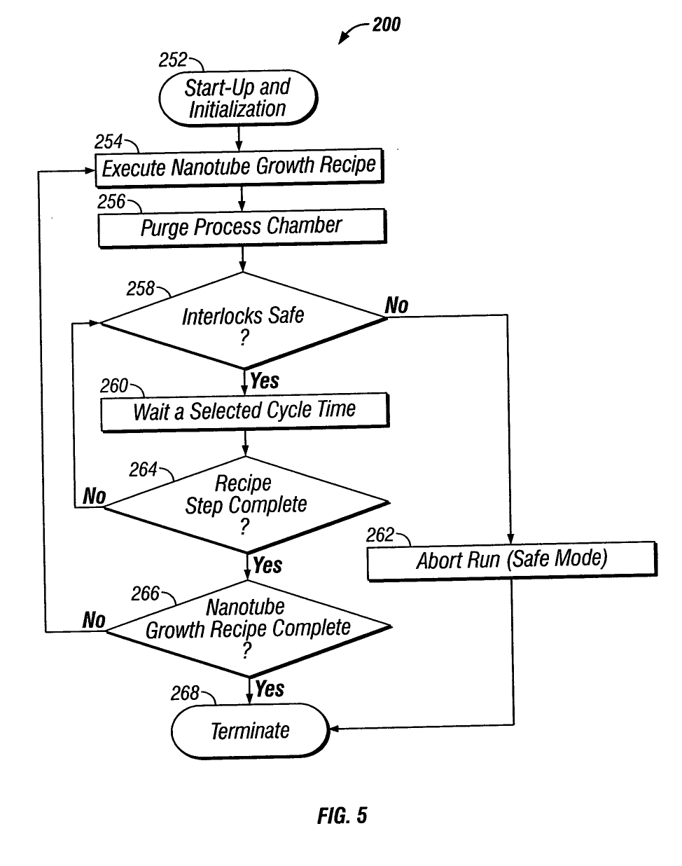

There are three sensors situated to detect a potentially hazardous situation within the gas delivery unit 14. A differential pressure sensor (P1) 204 indicates whether the unit is sufficiently exhausted by measuring the pressure within the unit with respect to the atmospheric pressure of the room. A flow sensor (F1) 206 situated within the exhaust outlet 210, together with system control, provide an indication of whether there is a sufficient amount of exhaust flow exiting the unit based primarily on the flow rate of the process gasses. Alternatively, this sensor could be situated to measure the flow entering the unit from the room with equivalent results. Also, a combustible gas detector (C1) 208 is located within the gas delivery unit 14 to indicate the presence of a gas leak. Gas detector 208 measures, for example, a concentration of methane in unit 14 and transmits the information to computer control unit 16. The three sensors are connected to the computer control unit 16 where their readings may be utilized, for example, to maintain safe operating conditions of the system as described below in conjunction with FIG. 5. Overall, such sensors are conventional for performing their stated functions.

Pressure sensor (P1) 204 and flow sensor (F1) 206 may be considered redundant. Each indicates whether the unit is sufficiently exhausted of potentially dangerous gas. It may suffice to have only one of these two sensors 204, 206 installed for safe operation.

Process chamber (18 in FIG. 1) must also be connected to facility exhaust 202. Process gasses leaving the process chamber pass through an exhaust manifold 212 where they are allowed to cool before entering exhaust outlet 224 of facility exhaust 202. The exhaust gasses, at this point, mix with air.

The process waste gas may be diluted with a non-reactive gas via a plumbing line (not shown) to exhaust manifold 212 before passing on to the facility exhaust 202. The exhaust manifold 212 incorporates a differential pressure sensor (P2) 218 and a flow sensor (F2) 220, which are connected to the computer control unit 16. In the proximity of exhaust manifold 212 is a combustible gas detector (C2) 222 to measure, for example, concentration(s) selected gas(es) so as to detect leaks from exhaust manifold 212. The outputs of the three sensors 218, 220, 222 are connected to the computer control unit 16 where their readings may be utilized to maintain safe operating conditions of system 200.

The pressure sensor (P2) 218 and the flow sensor (F2) 220 may be considered redundant. Each indicates whether the process gasses are sufficiently exhausted. It may suffice to have only one of these two sensors 218, 220 installed for safe operation.

A preferred method 250 of processing the data provided by sensors (204, 206, 208, 218, 220, 222 in FIG. 4) to control the carbon nanotube growth apparatus continuously during execution of a nanotube growth recipe is illustrated in FIG. 5. Note that the terms interlock or interlocking used herein preferably refer to controlling the growth process based on the data provided by the sensors. When a carbon nanotube growth recipe is initiated, a start-up and initialization Block 252 is executed. In Block 256, an inert gas purge may be performed. In order to be certain that the process chamber has been sufficiently purged of oxygen, a predetermined volume of inert gas is to be delivered to the process chamber over a predetermined period of time, as outlined previously. Flow is measured by the mass-flow controllers (24 in FIG. 1) in units of volume per unit time. To sufficiently purge the process chamber, the volume of purge gas should be greater than the volume of the process chamber 18. Again, the required volume of purge gas is correctly metered to the process chamber by maintaining a specific flow over a period of time (i.e., flow*time=volume).

After the process chamber is purged of oxygen, a nanotube growth recipe is executed in an iterative, step-wise fashion. More particularly, in Block 256, method 250 initiates a loop wherein each recipe step is executed for a loop cycle until the recipe is complete. For each recipe step, the computer will perform the tasks of setting the gas flow set-points and setting the temperature set-point, for instance, in accordance with known or custom nanotube growth recipes.

In Block 258, method 100 decides whether to continue or to abort based upon the data gathered in reading the various process sensors (204, 206, 208, 218, 220, 222 in FIG. 4). Typically, the following “interlock” conditions must be met for the recipe to continue: differential pressure sensors (P1) 204 and (P2) 218 must read sufficient pressure, flow sensors (F1) 206 and (F2) 220 must read sufficient flow, and combustible gas detectors (C1) 208 and (C2) 222 must read negative for the presence of combustible gas. For example, a selected (relatively low, approximately 0.5 inches of water) pressure must be maintained within system enclosures to insure that process gasses do not seep from the apparatus. Moreover, a predetermined rate of flow of the exhaust gasses (for example, determined empirically) must be maintained. If the designated flow is not maintained, the system will conclude that an insufficient amount of process gasses are being exhausted during process. This may occur if a leak exists in the enclosures.

If all these conditions are satisfied based on the sensor readings, then the instrument may be considered to be safe and the process run will continue with the method 250 proceeding to Block 260, a wait step having a selected duration. However, if any one these conditions is not met, then the instrument may be considered to be in an unsafe state. Therefore, the next step in the sequence will be an abort run, Block 262.

The abort run step of Block 262 places the system in a safe condition and, preferably, notifies the operator that an error has occurred. A safe condition preferentially includes stopping the flow of any combustible process gasses to the chamber, discontinuing any heat that may be applied to the process chamber, and locking out any potentially dangerous operator commands until the malfunction is rectified. This sequence then continues to terminate the process at Block 268, without completing the nanotube growth recipe.

Assuming safe conditions, the wait step of Block 260 causes a recipe step to be executed for a predetermined duration (i.e., a cycle) associated with that step of the nanotube growth process. After this predetermined time, method 250 determines whether the corresponding step of the recipe is complete in Block 264. Recipe steps generally define durations wherein the temperature is either maintained or ramped and gas flows are maintained at their set-points. For example, first ramp furnace temperature to nanotube growth temperature (typically a specific temperature between 600 and 900 deg Celsius) while flowing an inert gas such as Argon. Then hold temperature at nanotube growth temperature time (typically 5 to 60 minutes) while flowing nanotube growth reagent gasses which may include one or more of the following: methane, acetylene, ethylene, butane, hydrogen. Thereafter the recipe may instruct “cool to room temperature” while flowing inert gas, such as Argon.

The safety interlocks will be checked repeatedly throughout each growth recipe step, and the program will branch to the abort step (Block 262) at any point instrument operation becomes potentially unsafe. The program flow will loop back to determine whether the system 200 is safe by reading and processing the data obtained by sensors 204, 206, 208, 218, 220, 222 in the interlock safe Block 258 until the recipe step is complete.

Upon completion of the recipe step, the program will continue to Block 266 to determine whether the nanotube growth recipe is complete. Typically, the last instruction in the recipe will typically be an end instruction. If the recipe is not complete, then the program will return to the get recipe instruction (next recipe Step) Block 256. If the instruction is an end instruction, the recipe is complete and the program will continue to stop Block 268 to terminate the program 250.

Although the best mode contemplated by the inventors of carrying out the present invention is disclosed above, practice of the present invention is not limited thereto. It will be manifest that various additions, modifications and rearrangements of the features of the present invention may be made without deviating from the spirit and scope of the underlying inventive concept. The scope of still other changes to the described embodiments that fall within the present invention but that are not specifically discussed above will become apparent from the appended claims.

What is claimed is:

1. A method of fabricating carbon nanotubes in a nanotube growth apparatus, the method comprising the steps of:
executing a nanotube growth process recipe;
monitoring a safety condition during said executing step; and
continuously controlling said executing step based on said monitoring step.

2. The method of claim 1, wherein the safety condition is associated with at least one of a group including a pressure in an exhaust pathway, a flow in the exhaust pathway, and a predetermined amount of a combustible gas in the apparatus.

3. The method of claim 1, wherein said executing step occurs for a predetermined time period.

4. The method of claim 3, wherein said predetermined time period defines a selected number of cycles.

5. The method of claim 4, wherein said monitoring step includes reading a plurality of sensors.

6. The method of claim 5, wherein said reading step is performed after each cycle.

7. The method of claim 5, wherein said sensors include at least one of a group including a pressure sensor, a flow sensor and a combustible gas sensor.

8. The method of claim 7, wherein said sensors include at least one pressure sensor, at least one flow sensor and at least one combustible gas sensor.

9. The method of claim 1, wherein said controlling step includes aborting said executing step in response to said monitoring step.

10. The method of claim 9, further comprising purging the process chamber after said aborting step.

11. A nanotube growth apparatus comprising:
a furnace including a process chamber;
a gas delivery unit;
an exhaust sub-system coupled to said furnace and said gas delivery unit; and
a sensor that detects at least one of a group including a pressure in the apparatus, a gas flow in the apparatus and presence of a combustible gas in the apparatus.

12. The apparatus of claim 11, further comprising a plurality of sensors.

13. The apparatus of claim 11, wherein said sensor includes a gas flow sensor disposed in said exhaust subsystem.

14. The apparatus of claim 11, wherein said sensor generates an output signal during execution of a nanotube growth recipe, said output signal being transmitted to a computer.

15. The apparatus of claim 14, wherein the computer controls execution of the nanotube growth recipe in response to said output signal.

16. The apparatus of claim 15, wherein at least a first step of the nanotube growth recipe is executed, and said computer processes said output signal after each of a predetermined number of cycles during execution of said first step.

17. The apparatus of claim 15, wherein the computer causes the apparatus to enter an abort state based on said output signal.

18. The apparatus of claim 17, wherein said abort state is defined by at least one operation.

19. The apparatus of claim 18, wherein the operation is a purge operation to purge process gasses from the process chamber.

20. The apparatus of claim 11, wherein said exhaust subsystem includes an exhaust manifold and said sensor is positioned in said exhaust manifold.

21. The apparatus of claim 11, further including a vacuum source for modifying a nanotube growth dynamic.

22. The apparatus of claim 21, wherein the nanotube growth dynamic is growth rate.

23. A monitoring system for a nanotube growth apparatus having a furnace including a process chamber, the system comprising:
a network of sensors that measure at least one of a group including gas flow, presence of a combustible gas and a pressure, each of said sensors generating a corresponding fault signal; and
a control system interlocked to at least one of said fault signals to control operation of the nanotube growth apparatus.

24. The monitoring system of claim 23, wherein said control system aborts operation of the nanotube growth apparatus based on at least one of said fault signals.

25. The monitoring system of claim 24, wherein said control system generates a purge signal in response to at least one of said fault signals, and transmits said purge signal to a gas delivery unit to purge the process chamber with an inert gas.

26. The monitoring system of claim 25, wherein the nanotube growth apparatus includes an exhaust sub-system, and at least one flow sensor is place in said exhaust sub-system.

27. The monitoring system of claim 26, wherein the network of sensors includes at least one flow sensor positioned in said exhaust sub-system, at least one pressure sensor in said gas delivery unit, and at least one combustible gas detector in an enclosure of the nanotube growth apparatus.

28. A monitoring system for a nanotube growth apparatus having a furnace including a process chamber, the system comprising:
means for sensing at least one of a gas flow, a presence of a combustible gas and a pressure in the apparatus; and
means for continuously controlling execution of a nanotube growth recipe based on an output of said sensing means.

29. The monitoring system of claim 28, wherein said sensing means is disposed in at least one of a gas delivery unit, an exhaust sub-system and the furnace.

30. The monitoring system of claim 29, wherein said sensing means includes a network of sensors.

31. The monitoring system of claim 28, wherein said network of sensors includes at least one sensor in said exhaust sub-system, at least one sensor in said gas-delivery unit and at least one sensor in the furnace.

32. The monitoring system of claim 28, wherein said means for controlling places the apparatus in an abort state when the output indicates a fault condition.

33. The monitoring system of claim 32, wherein the apparatus includes a heat control unit and said controlling means disables said heat control unit in the abort state.

34. The monitoring system of claim 32, wherein said means for controlling activates a means for purging the process chamber in the abort state.

35. The monitoring system of claim 34, wherein said means for purging includes a flow control unit that flows an inert gas through the process chamber.

36. The monitoring system of claim 28, further comprising a means for altering a reaction rate associated with nanotube growth.

37. The monitoring system of claim 36, wherein said altering means is a vacuum source.

38. The monitoring system of claim 37, wherein said vacuum source lowers a pressure in the process chamber to slow nanotube growth.
